(19) United States
(12) Patent Application Publication
(10) Pub. No.: US 2025/0112613 A1
(43) Pub. Date: Apr. 3, 2025

(54) SCATTERING ELEMENTS FOR COUPLING PREVENTION WITH ELECTROACOUSTIC RESONATORS

(71) Applicant: RF360 SINGAPORE PTE. LTD., Republic Plaza (SG)

(72) Inventors: Ansgar SCHAEUFELE, Munich (DE); Armin ZEITLER, München (DE); Joerg HORNSTEINER, Mittenwald (DE)

(21) Appl. No.: 18/478,585

(22) Filed: Sep. 29, 2023

(51) Int. Cl. H03H 9/02; H03H 9/13

(52) U.S. Cl. CPC H03H 9/02118; H03H 9/02023; H03H 9/131

(57) ABSTRACT

An apparatus is provided for coupling prevention with electroacoustic resonators using scattering elements. In one example, an apparatus comprises a piezoelectric layer comprising a shared surface, a first resonator comprising a first interdigital transducer disposed over the shared surface of the piezoelectric layer, a second resonator comprising a second interdigital transducer disposed over the shared surface of the piezoelectric layer, and a plurality of scattering elements positioned between the first resonator and the second resonator.

### TECHNICAL FIELD

The present disclosure relates generally to electronic communications. For example, aspects of the present disclosure relate to electroacoustic resonators, and in particular, to inclusion of a scattering element to prevent coupling between electroacoustic resonators on a shared piezoelectric surface.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on.

Electronic devices may be capable of supporting communication with multiple users by sharing available communications resources (e.g., time, frequency, and power). Examples of communications protocols include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high-frequency (e.g., generally greater than 100 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices such as cellular phones).

### SUMMARY

Disclosed are systems, apparatuses, methods, and computer-readable media for coupling prevention using scattering elements with electroacoustic resonators.

According to at least one example, a method is provided for coupling prevention with resonators using scattering elements. The method includes: receiving, at a filter comprising a resonator, a wireless communication signal, where the filter comprises a piezoelectric layer comprising a first surface, a first resonator comprising a first interdigital transducer disposed over the first surface of the piezoelectric layer, and a plurality of scattering elements positioned adjacent to the first resonator, exciting the resonator using the wireless communication signal to generate acoustic energy in an acoustic mode of the resonator, and dispersing acoustic energy from the acoustic mode of the resonator using the plurality of scattering elements.

Some such aspects operate where the piezoelectric layer further comprises an edge, where the plurality of scattering elements are further positioned between the first resonator and the edge, and where the plurality of scattering elements further configured to disperse acoustic energy from an acoustic reflection from the acoustic mode of the first resonator reflected off the edge of the piezoelectric layer.

Some such aspects operate where the piezoelectric layer further comprises a second resonator, with the scattering elements positioned between the first resonator and the second resonator, and where the plurality of scattering elements are configured to disperse acoustic energy from an acoustic mode of the second resonator that is different than an acoustic mode of the first resonator. Some such aspects operate where a shortest dimension across a scattering element of the plurality of scattering elements is greater than 0.1 times a wavelength of a resonance frequency of the first resonator or a wavelength of a resonance frequency of the second resonator, where a longest dimension across a scattering element of the plurality of scattering elements is less than 10 times a wavelength of a resonance frequency of the first resonator or a wavelength of a resonance frequency of the second resonator, where a shortest dimension between adjacent scattering elements of the plurality of scattering elements is greater than 0.1 times a wavelength of a resonance frequency of the first resonator or a wavelength of a resonance frequency of the second resonator, and where a longest dimension between adjacent scattering elements of the plurality of scattering elements is less than 10 times a wavelength of a resonance frequency of the first resonator or a wavelength of a resonance frequency of the second resonator.

In another example, an apparatus is provided. The apparatus comprises a piezoelectric layer comprising a first surface and a first edge, a first resonator comprising a first interdigital transducer disposed over the first surface of the piezoelectric layer, and a plurality of scattering elements positioned between the first resonator and the first edge of the piezoelectric layer.

In another example, an apparatus for coupling prevention with electroacoustic devices is provided. The apparatus includes: a piezoelectric layer comprising a shared surface, a first resonator comprising a first interdigital transducer disposed over the shared surface of the piezoelectric layer, a second resonator comprising a second interdigital transducer disposed over the shared surface of the piezoelectric layer, and a plurality of scattering elements positioned between the first resonator and the second resonator.

In some aspects, the plurality of scattering elements are configured to disperse acoustic energy from an acoustic mode of the first resonator and to disperse acoustic energy from an acoustic mode of the second resonator.

In some aspects, a shortest dimension across a scattering element of the plurality of scattering elements is greater than 0.1 times a wavelength of a resonance frequency of the first resonator or a wavelength of a resonance frequency of the second resonator.

In some aspects, a longest dimension across a scattering element of the plurality of scattering elements is less than 10 times a wavelength of a resonance frequency of the first resonator or a wavelength of a resonance frequency of the second resonator.

In some aspects, a shortest dimension between adjacent scattering elements of the plurality of scattering elements is greater than 0.1 times a wavelength of a resonance frequency of the first resonator or a wavelength of a resonance frequency of the second resonator.

In some aspects, a longest dimension between adjacent scattering elements of the plurality of scattering elements is less than 10 times a wavelength of a resonance frequency of the first resonator or a wavelength of a resonance frequency of the second resonator.

In some aspects, a first busbar, and a second busbar, where the first interdigital transducer (IDT) comprises a first plurality of IDT electrode fingers comprising first IDT electrode fingers extending from the first busbar toward the second busbar and second IDT electrode fingers extending from the second busbar toward the first busbar in an interdigitated configuration.

In some aspects, the plurality of scattering elements are aligned along a line perpendicular to the first busbar and the second busbar, such that an extension of a track of the first resonator intersects with the line.

In some aspects, the plurality of scattering elements are positioned in a path extending from a track of the first resonator.

In some aspects, the plurality of scattering elements are positioned in a vicinity of a resonator independent of a resonator orientation.

In some aspects, the plurality of scattering elements comprise voids within the piezoelectric layer.

In some aspects, the plurality of scattering elements comprise metal, dielectric, or semiconducting material disposed on the piezoelectric layer.

In some aspects, the plurality of scattering elements have a thickness that is at least 0.1 times a thickness of a metal layer of the first interdigital transducer.

In some aspects, a metal contact coupled to the first busbar, where the plurality of scattering elements are formed in a shared layer with the metal contact.

In some aspects, the plurality of scattering elements comprise circular geometries.

In some aspects, the plurality of scattering elements comprise elements with two or more distinct geometries.

In some aspects, a second plurality of scattering elements positioned between the first resonator and an edge of the piezoelectric layer

In some aspects, one or more of the apparatuses described herein is, is part of, and/or includes a mobile device (e.g., a mobile telephone and/or mobile handset and/or so-called “smartphone” or other mobile device), an extended reality (XR) device (e.g., a virtual reality (VR) device, an augmented reality (AR) device, or a mixed reality (MR) device), a head-mounted device (HMD) device, a vehicle or a computing system, device, or component of a vehicle, a wearable device (e.g., a network-connected watch or other wearable device), a wireless communication device, a camera, a personal computer, a laptop computer, a server computer, another device, or a combination thereof. In some aspects, the apparatus includes a camera or multiple cameras for capturing one or more images. In some aspects, the apparatus further includes a display for displaying one or more images, notifications, and/or other displayable data. In some aspects, the apparatuses described above can include one or more sensors (e.g., one or more inertial measurement units (IMUs), such as one or more gyroscopes, one or more gyrometers, one or more accelerometers, any combination thereof, and/or other sensors).

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and aspects, will become more apparent upon referring to the following specification, claims, and accompanying drawings.

### BRIEF DESCRIPTION OF DRAWINGS

FIG. 1A is a diagram of a perspective view of an example of an electroacoustic resonator.

FIG. 1B is a diagram of a side view of the electroacoustic resonator of FIG. 1A.

FIG. 2A is a diagram of a top view of an example of an electrode structure of an example electroacoustic resonator.

FIG. 2B is a diagram of a top view of an example of an electrode structure of an example electroacoustic resonator.

FIG. 3A is a diagram of a perspective view of another example of an electroacoustic resonator.

FIG. 3B is a diagram of a side view of the electroacoustic resonator of FIG. 3A.

FIG. 4 is a diagram of a view of an example electrode structure of an interdigital transducer (IDT) that can be used in a device with multiple electroacoustic resonators and scattering elements in accordance with aspects described herein.

FIG. 5 is a diagram of an apparatus comprising two electroacoustic resonators on a shared piezoelectric surface with scattering elements to prevent coupling in accordance with aspects described herein.

FIGS. 6A-G illustrate aspects of devices comprising two electroacoustic resonators on a shared piezoelectric surface with scattering elements to prevent coupling in accordance with aspects described herein.

FIG. 7 illustrates aspects of scattering elements in accordance with some aspects described herein.

FIG. 8A illustrates aspects of a device comprising scattering elements in accordance with some aspects described herein.

FIG. 8B illustrates aspects of a device comprising scattering elements in accordance with some aspects described herein.

FIG. 9 is a flowchart illustrating a method of operation of the disclosed electroacoustic devices, in accordance with examples described herein.

FIG. 10 is a schematic representation of an example filter that may employ the disclosed electroacoustic device, in accordance with examples described herein.

FIG. 11 is a functional block diagram of at least a portion of an example of a simplified wireless transceiver circuit in which the disclosed electroacoustic device described herein may be employed, in accordance with examples described herein.

FIG. 12 is a diagram of an environment that includes an electronic device that includes a wireless transceiver, such as the transceiver circuit of FIG. 11, in accordance with examples described herein.

### DETAILED DESCRIPTION

The detailed description set forth below in connection with the appended drawings is intended as a description of example implementations and is not intended to represent the only implementations in which the invention may be practiced. The detailed description includes specific details for the purpose of describing aspects of devices (e.g., surface acoustic wave (SAW) devices) in a configuration including scattering elements to suppress or prevent coupling between resonators on a shared piezoelectric surface.

Electroacoustic devices (e.g., “acoustic filters”) can be used to filter high-frequency (e.g., generally greater than 100 MHZ) signals in many applications. An electroacoustic filter is tuned to pass certain frequencies (e.g., frequencies within its passband) and attenuate other frequencies (e.g., frequencies that are outside of its passband). Using a piezoelectric material as a vibrating medium in a transducer, the acoustic filter operates by transforming an electrical signal wave that is propagating along an electrical conductor into an acoustic wave (e.g., an acoustic signal wave) that forms across the piezoelectric material. The acoustic wave is then converted back into an electrical filtered signal. The cellular communication market, in particular, uses such electroacoustic devices. Within the cellular market, the market for wearable devices is growing at a very high rate. Aspects described herein can provide an improvement to such wearable devices, where very light and small devices with very high efficiency are prioritized over devices consuming higher power.

Given the value of space and reduced size for wireless communication devices, elements within such devices are designed to be as close as possible while maintaining acceptable performance. As electroacoustic resonators are positioned in close proximity, coupling between devices can occur, reducing device performance. Adding additional space between devices to limit coupling is not a preferred solution, as this increases device size.

Aspects described herein include piezoelectric materials with more than one resonator disposed on the piezoelectric material. Two of the resonators may be positioned on either side of scattering elements to prevent or suppress coupling between the resonators. The scattering elements operate to disperse acoustic waves outside the confines of individual resonators, to prevent the waves from impacting the adjacent resonator. Such scattering elements can operate in both directions, reducing the energy in acoustic waves from both resonators on either side of the scattering elements.

In some aspects, the scattering elements can be either voids in the piezoelectric layer or materials (e.g., any signal scattering materials, including metal or any other such material that can lead to a scattering effect in resonators as described herein) disposed on the piezoelectric layer in a roughly linear position between two resonators. As an acoustic wave from one resonator interacts with the scattering elements, portions of the acoustic wave are reflected or deflected, dispersing the energy of the acoustic wave from the originating resonator to limit the amount of energy that impacts the adjacent resonator. Scattering elements of different sizes and shapes are possible within the scope of the described aspects, and can be specially configured to the frequencies of the two resonators on either side of the scattering elements.

Inclusion of such scattering elements in a device can reduce device size, while improving amplitude ripple, roll-off, unwanted out-of-band dips, and other frequency performance of an individual resonator. In some aspects, such improvements can be achieved without additional stack layers or fabrication processes for a given electroacoustic design.

Various aspects of the present disclosure will be described with respect to the figures.

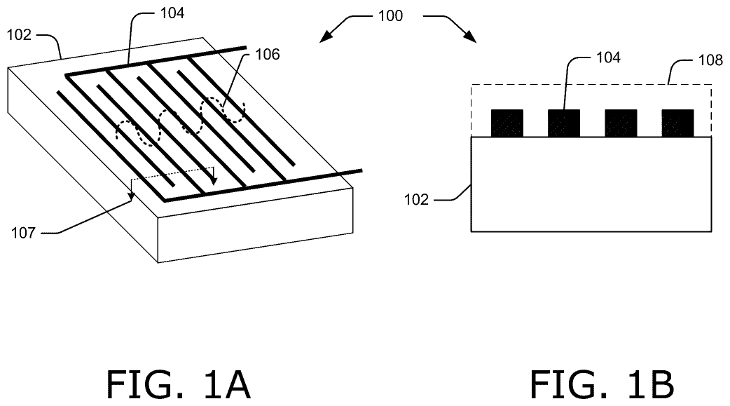

FIG. 1A is a diagram of a perspective view of an example of an electroacoustic transducer 100. The electroacoustic transducer 100 may be configured as, or be a portion of, a SAW resonator. In certain descriptions herein, the electroacoustic transducer 100 may be referred to as a SAW resonator. The electroacoustic transducer 100 includes an electrode structure 104, that may be referred to as an interdigital transducer (IDT), on the surface of a piezoelectric material 102. The electrode structure 104 generally includes first and second comb shaped electrode structures (conductive and generally metallic) with electrode fingers extending from two busbars towards each other arranged in an interlocking manner in between two busbars (e.g., arranged in an interdigitated manner). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a diagram of a side view of the electroacoustic transducer 100 of FIG. 1A, along a cross-section 107 shown in FIG. 1A. The electroacoustic transducer 100 is illustrated by a simplified layer stack including a piezoelectric material 102 with an electrode structure 104 disposed on the piezoelectric material 102. The electrode structure 104 is conductive and generally formed from metallic materials. The piezoelectric material may be formed from a variety of materials such as quartz, lithium tantalate (LiTaO3), lithium niobate (LiNbO3), doped variants of these, or other piezoelectric materials. It should be appreciated that more complicated layer stacks (e.g., four (4) layers, six (6) layers, etc.), including layers of various materials, may be possible within the stack. For example, optionally, a temperature compensation layer 108 (denoted by the dashed lines) may be disposed above the electrode structure 104. The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip-chip or other techniques) may also be included.

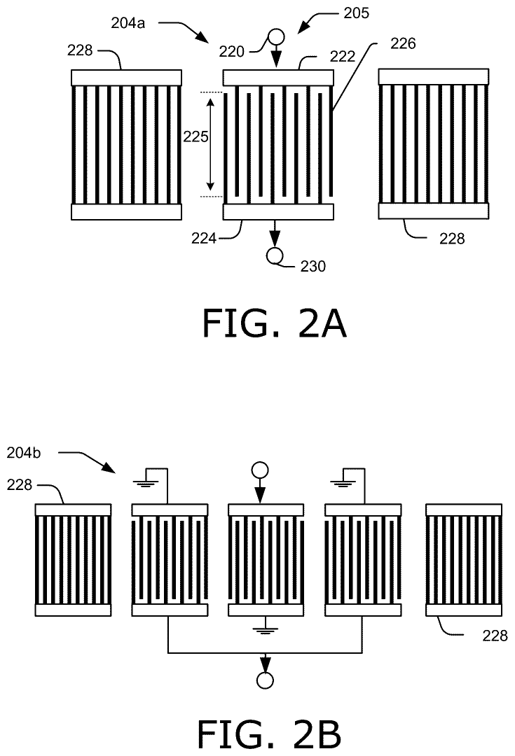

FIG. 2A is a diagram of a top view of an example of an electrode structure 204a of the electroacoustic transducer 100 configured with two reflectors 228 in a non-DMS configuration. FIG. 2A generally illustrates a one-port configuration. The electrode structure 204a has an IDT 205 that includes a first busbar 222 (e.g., first conductive segment or rail) electrically connected to a first terminal 220 and a second busbar 224 (e.g., second conductive segment or rail) spaced from the first busbar 222 and connected to a second terminal 230. A plurality of conductive fingers 226 are connected to either the first busbar 222 or the second busbar 224 in an interdigitated manner. Fingers 226 connected to the first busbar 222 extend towards the second busbar 224 but do not connect to the second busbar 224 so that there is a small gap between the ends of these fingers 226 and the second busbar 224. Likewise, fingers 226 connected to the second busbar 224 extend towards the first busbar 222 but do not connect to the first busbar 222 so that there is a small gap between the ends of these fingers 226 and the first busbar 222.

In the direction along a shared line parallel to the busbars 222 and 224, there is an overlap region including a central region where a portion of one finger overlaps with a portion of an adjacent finger (as illustrated by the central region 225). The central region 225 including the overlap may be referred to as the aperture, track, or active region where electric fields are produced between fingers 226 to cause an acoustic wave to propagate in the piezoelectric material 102. The periodicity of the fingers 226 is referred to as the pitch of the IDT. The pitch may be indicated in various ways. For example, in certain aspects, the pitch may correspond to a magnitude of a distance between fingers in the central region 225. The distance may be defined, for example, as the distance between center points of each of the fingers (and may be generally measured between a right (or left) edge of one finger and the right (or left) edge of an adjacent finger when the fingers have uniform thickness). As described herein, a “higher” pitch refers to sections of an IDT where electrode fingers have greater distances between adjacent electrode fingers, and a “lower” pitch refers to sections of an IDT where electrode fingers have lower distances between adjacent electrode fingers. In certain aspects, an average of distances between adjacent fingers may be used for the pitch. Having sections of an IDT with electrode fingers having a given pitch characteristic different from pitch characterizations of other sections of an IDT allows for selection or control of the signals (e.g., waves) that propagate through the IDT. The frequency at which the piezoelectric material vibrates is a self-resonance (also called a “main-resonance”) frequency of the electrode structure 204a. The frequency is determined at least in part by the pitch of the IDT 205 and other properties of the electroacoustic transducer 100.

In some examples, the pitch characteristics of sections of an IDT can be a constant pitch, where the pitch does not vary significantly over the IDT section (e.g., variances are within manufacturing tolerances, and are designed for a constant average pitch). In other examples, pitch characteristics of an IDT section can include a “chirped” pitch, where the pitch varies in a predefined way over the IDT section. For example, a chirped pitch can include an IDT section where the pitch is designed to change linearly across the IDT section, such that the pitch at one end of the IDT section is at a first value, the pitch at an opposite end of the IDT section is at a second value, and the pitch (e.g., the distance between electrode fingers) changes linearly between the two ends of the IDT section. In other examples, other non-linear variations in pitch value across an IDT section can be used. By combining IDT sections with different pitch characteristics (e.g., a constant pitch at a first value and a constant pitch at a second value, or a constant pitch at a first value in one IDT section and a chirped pitch across a second IDT section), the resonator characteristics can be designed for a given performance as described herein.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars along shared lines with corresponding busbars for the IDT 205 and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the measured admittance or reactance between both terminals (i.e. the first terminal 220 and the second terminal 230) serves as the signal for the electroacoustic transducer 100.

FIG. 2B is a diagram of a top view of another example of an electrode structure 204b of an electroacoustic device. In this case, the electrode structure 204b includes a central IDT along with reflectors 228 connected as illustrated. The electrode structure 204b is provided to illustrate the variety of electrode structures and connections for structures that can be used in accordance with aspects described herein.

It should be appreciated that while a certain number of fingers 226 are illustrated, the number of actual fingers and lengths and width of the fingers 226 and busbars may be different in an actual implementation. Such parameters depend on the particular application and desired frequency of the filter. In addition, a SAW filter may include multiple interconnected electrode structures each including multiple IDTs to achieve a desired passband (e.g., multiple interconnected resonators or IDTs to form a desired filter transfer function).

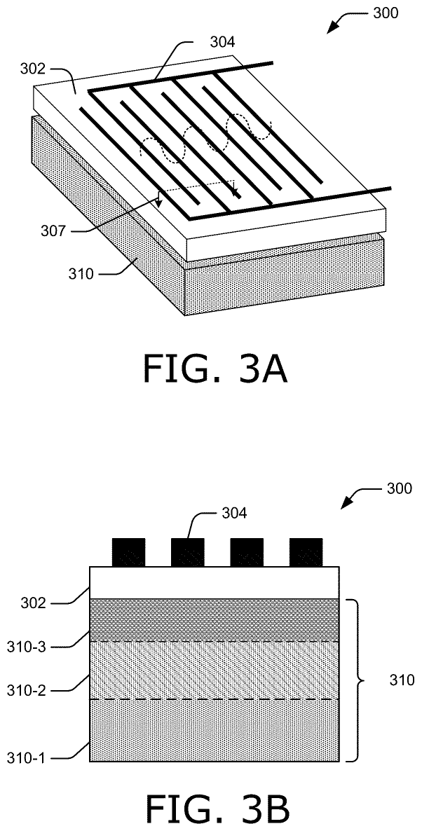

FIG. 3A is a diagram of a perspective view of another example of an electroacoustic device 300. The electroacoustic device 300 (e.g., that may be configured as or be a part of a SAW resonator) is similar to the electroacoustic transducer 100 of FIG. 1A, but has a different layer stack. In particular, the electroacoustic device 300 includes a thin piezoelectric material 302 that is provided on a substrate 310 (e.g., silicon). Based on the type of piezoelectric material 302 used (e.g., typically having higher coupling factors relative to the electroacoustic transducer 100 of FIG. 1A) and a controlled thickness of the piezoelectric material 302, the particular acoustic wave modes excited may be slightly different than those in the electroacoustic transducer 100 of FIG. 1A. Based on the design (thicknesses of the layers, and selection of materials, etc.), the electroacoustic device 300 may have a higher Q-factor as compared to the electroacoustic transducer 100 of FIG. 1A. The piezoelectric material 302, for example, may be Lithium tantalate (LiTa03) or some doped variant. Another example of a piezoelectric material 302 for FIG. 3A may be Lithium Niobate (LiNbO3). In general, the substrate 310 may be substantially thicker than the piezoelectric material 302 (e.g., potentially on the order of 50 to 100 times thicker as one example—or more). The substrate 310 may include other layers as 310-1, 310-2, and 310-3 (or other layers may be included between the substrate 310 and the piezoelectric material 302).

FIG. 3B is a diagram of a side view of the electroacoustic device 300 of FIG. 3A showing an example of a layer stack (along a cross-section 307). In the aspect shown in FIG. 3B, the substrate 310 may include sublayers such as a substrate sublayer 310-1 (e.g., of silicon) that may have a higher resistance (e.g., relative to the other layers-high resistivity layer). The substrate 310 may further include a trap rich layer 310-2 (e.g., poly-silicon, aluminum nitride (AlN), silicon nitride (SiN4), diamond-like carbon (DLC), and dielectric films with a high sound velocity). The substrate 310 may further include a compensation layer (e.g., silicon dioxide (SiO2) or another dielectric material) that may provide temperature compensation and other properties. These sub-layers may be considered part of the substrate 310 or their own separate layers. A relatively thin piezoelectric material 302 is provided on the substrate 310 with a particular thickness for providing a particular acoustic wave mode (e.g., as compared to the electroacoustic transducer 100 of FIG. 1A where the thickness of the piezoelectric material 102 may not be a significant design parameter beyond a certain thickness and may be generally thicker as compared to the piezoelectric material 302 of the electroacoustic device 300 of FIGS. 3A and 3B). The electrode structure 304 is positioned above the piezoelectric material 302. In addition, in some aspects, there may be one or more layers (not shown) possible above the electrode structure 304 (e.g., such as a thin passivation layer).

Based on the type of piezoelectric material, the thickness, and the overall layer stack, the electromechanical coupling to the electrode structure 304 and acoustic velocities within the piezoelectric material in different regions of the electrode structure 304 may differ between different types of electroacoustic devices such as between the electroacoustic transducer 100 of FIG. 1A and the electroacoustic device 300 of FIGS. 3A and 3B.

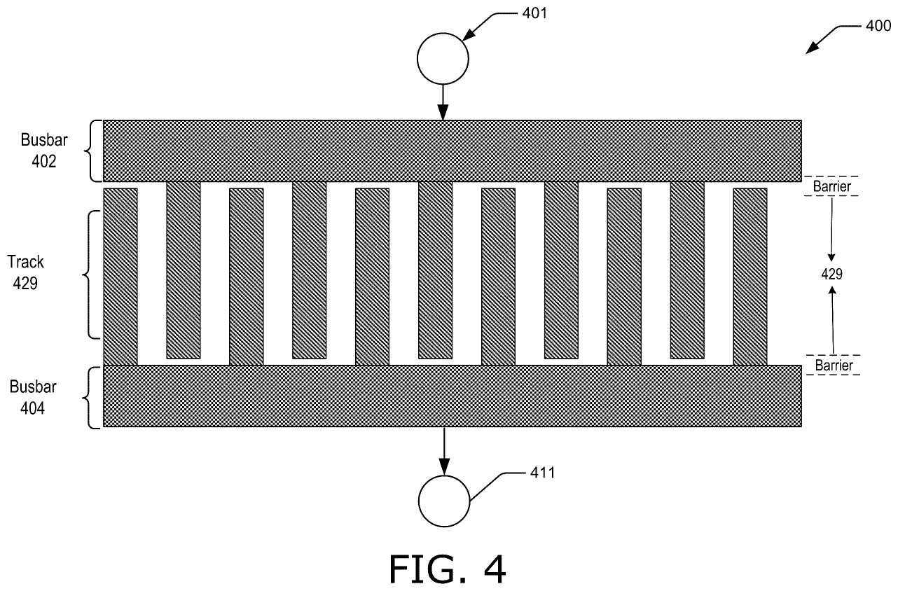

FIG. 4 is a diagram of a view of an example electrode structure 400 of an interdigital transducer (IDT) that can be used in a DMS in accordance with aspects described herein. Just as above, the electrode structure 400 may be referred to as an IDT that can be fabricated on the surface of a piezoelectric material as part of the resonator. The electrode structure 400 includes first and second comb shaped electrodes. The comb teeth are within track 429, and supported by busbar 402 on one side and busbar 404 on the other side. An electrical signal excited across the resonator by an electrical signal at input node 401 is transformed into an acoustic wave that propagates within the resonator. The acoustic wave is transformed back into an electrical signal at the output node 411. The outer reflectors (e.g., reflectors 228, not shown in FIG. 4) will have a similar configuration, but without the barrier, so that each finger of the reflectors couples across the track region to connect with both busbars.

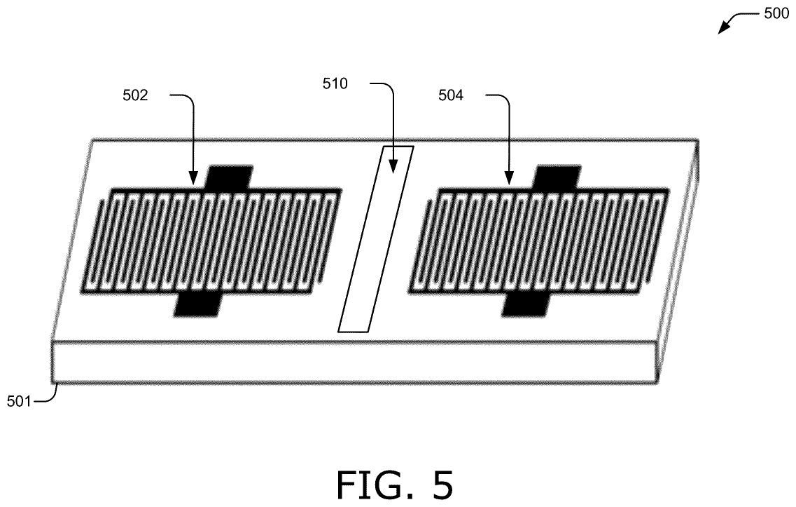

FIG. 5 is a diagram of an apparatus 500 comprising two electroacoustic resonators 502, 504 on a shared substrate 501 with scattering elements in an area 510 to prevent coupling in accordance with aspects described herein. Resonators formed with interdigital transducers on a piezoelectric substrate as described above can be subject to inter-resonator coupling, where acoustic energy from adjacent resonators interfere with resonator operations. In particular, such coupling can cause perturbations in passband behavior, resulting in dips in a transfer function of a filter that includes the resonator. Such behavior can increase filter passband amplitude ripple or impact linearity, reducing performance. Inter-resonator coupling can also cause dips in passband skirts and out-of-band spikes, which can further degrade performance via impacts on in band operation and cross element isolation.

As illustrated in FIG. 5, adjacent resonators 502 and 504 are positioned on a shared substrate 501, which will include a piezoelectric layer with IDTs of the resonators 502 and 504 disposed on a shared surface of the piezoelectric layer. FIG. 5 illustrates area 510, which can be an area used to position scattering elements. This area, in particular, at the end of the resonator tracks, is likely to be a path for acoustic energy escaping from individual resonators. Prior systems have used trenches or reflective objects in the area 510 to limit inter-device coupling. For example, a single large trench or metal bar in the area 510 could be used to limit coupling. Such single element designs to reduce coupling, however, can result in reflections or other negative device impacts that can reduce device performance.

Aspects described herein, rather than using single large trench or decoupling elements, use a plurality of scattering elements in the area 510 between adjacent resonators such as the resonators 502 and 504 to scatter acoustic energy. Such scattering avoids strong reflections which can result in unexpected and/or undesired impacts on other portions of a design. By using multiple scattering elements, acoustic energy is dispersed in a distributed fashion that is unlikely to cause unexpected spikes or coupling in undesired portions of a design.

To achieve effective scattering, small geometries are used for scattering elements, with dimensions for individual scattering elements between 0.1 and 10 times the wavelength of the acoustic wave from the adjacent resonators. Similarly, the distances between the scattering elements are between 0.1 and 10 times the wavelength of the acoustic waves generated by the adjacent resonators (e.g., the wavelength of the primary resonance mode of either resonator). The use of such geometries results in scattering of acoustic energy. Smaller geometries can result in acoustic energy passing through the scattering elements with limited impact, limited scattering, and limited suppression of inter-resonator coupling. Larger geometries can result in reflections causing undesired performance degradation or reflective coupling.

Additionally, while aspects described herein focus on suppression of acoustic energy between adjacent resonators, in some aspects, reflections from a piezoelectric surface edge or substrate edge can cause similar performance degradation. Scattering elements as described herein can be used between a resonator and a chip edge to scatter and diffuse acoustic energy that can degrade performance at an edge of a substrate due to reflections at the substrate edge.

Additionally, while the example of FIG. 5 shows a piezoelectric layer disposed on a separate substrate layer, in some aspects, the piezoelectric material can be used as the substrate, or the piezoelectric material can be implemented without a separate substrate layer. In such aspects, the examples described herein can be configured to operate with any described implementation, but without the separate described substrate layer.

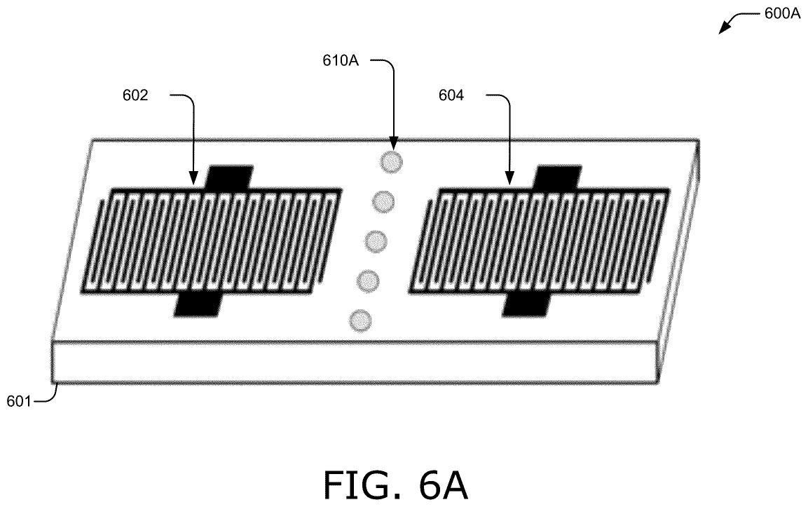

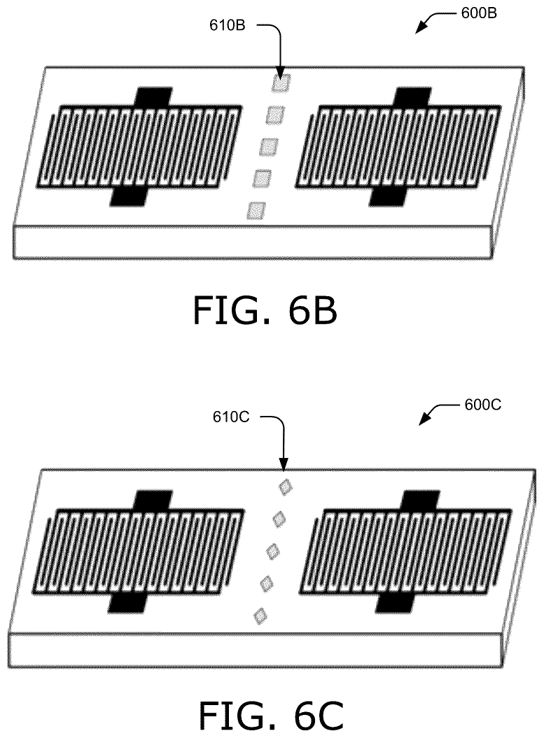

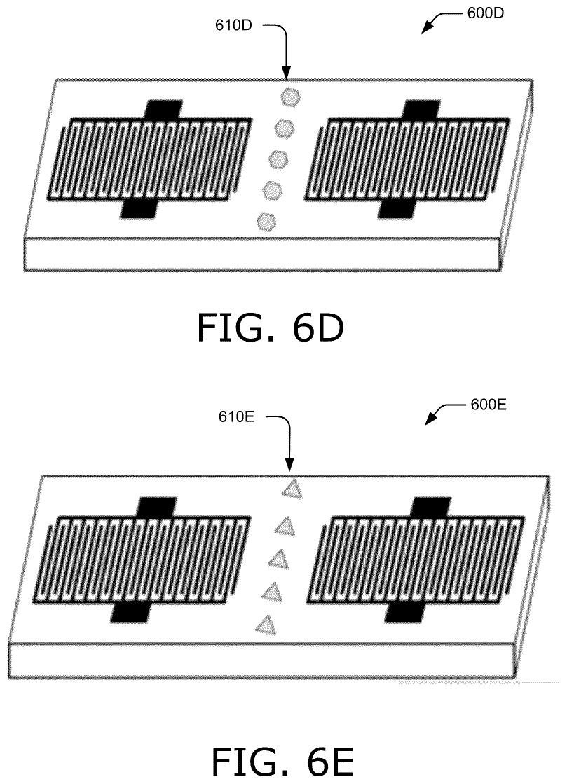

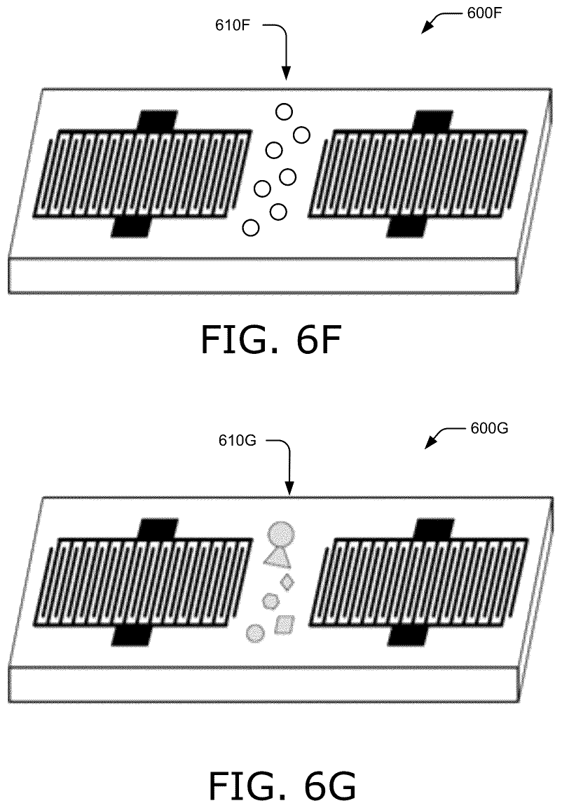

FIG. 6A illustrates aspects of an example device 600A comprising two electroacoustic resonators 602, 604 on a shared substrate 601 with scattering elements 610A to prevent coupling in accordance with aspects described herein. As illustrated, the scattering elements 610A include a plurality of circular elements. Other geometries can be used as detailed below. Similarly, the scattering elements 610A are illustrated to be positioned on a line between the resonators 602 and 604, with the geometries of the individual scattering elements and the geometries between the individual scattering elements based on the resonator 602, 604 operating wavelengths. Alternate relative positioning of the individual scattering elements is also possible as detailed below.

The use of such individual scattering elements of the scattering elements 610A allows for compact placement of the resonators 602, 604 to limit the size of the device 600A. The use of a plurality of small geometry scattering elements 610A also allows the scattering elements to be confined to a small area (e.g., the area 510) while providing scattering and dispersion of acoustic energy, as compared with a trench, where an angular offset of the area may be needed to avoid reflections back into a resonator, and where such an angular offset requires additional space on a design surface area. The use of such small geometry scatter elements 610A facilitates limiting the position of the scattering elements 610A to a narrow area between the resonators 602, 604.

FIGS. 6B-6F describe alternate scattering element geometries and placement in accordance with some aspects described herein. The device 600B includes scattering elements 610B with square geometries. The device 600C includes scattering elements 610C with diamond shaped geometries. The device 600D includes scattering elements 610D with hexagonal shaped geometries. The device 600E includes scattering elements 610E with triangle shaped geometries. While a particular set of individual scattering element geometries are described herein, any such geometry meeting the criteria described above can be used (e.g., a longest length across an individual scattering element less than 10 times the adjacent resonator wavelength(s), and a shortest length across an individual scattering element greater than 0.1 times the adjacent resonator wavelength(s). In some aspects, the geometries are selected based on the available manufacturing operations for a particular device. In other aspects, the geometries are selected based on design operations to select geometries for an individual implementation or chip layout that results in target performance. In some aspects, such as the devices 600C-E, the orientation of the individual scattering elements is selected such that straight edges of the resonator geometry are not parallel to the fingers of the adjacent IDT resonator. Particularly for larger geometries (e.g., closer to 10 times the adjacent resonator wavelength), such an orientation can reduce reflections of acoustic energy back to a resonator adjacent to the scattering elements.

Further, in FIGS. 6B-6E, the relative placements of the scattering elements 610B-E are roughly along a line between the adjacent resonators of the corresponding devices 600B-E. In other implementations, non-linear placement of scattering elements can be used. For example, FIG. 6F illustrates device 600F with scattering elements 610F positioned roughly along two lines between the adjacent resonators, with scattering elements along each line offset from scattering elements of an adjacent line. Such positioning of the scattering elements 610F can result in increased suppression of coupling and greater dispersion of acoustic energy at a cost of increased device size. Similarly, FIG. 6G illustrates device 600G with individual scattering elements of the scattering elements 610G having a non-uniform distribution in an area between the adjacent resonators, as well as having more than one geometry of the scattering elements (e.g., two or more distinct geometries, such as a hexagon and a square, or a circle and a stadium/stretched circular geometry in the same set of scattering elements. Such an implementation can provide increased scattering performance, again, at a cost of device size, and can be used to meet target performance criteria to reduce coupling between adjacent resonators. Additionally, in some aspects, placement of non-linear scattering elements as described can enable effective scattering for scattering element dimensions or separations smaller than 0.1 times the acoustic mode wavelength, or larger than 10 times the acoustic mode wavelength, depending on the particular configuration of the scattering elements to avoid reflections with sufficient dispersion of the acoustic energy.

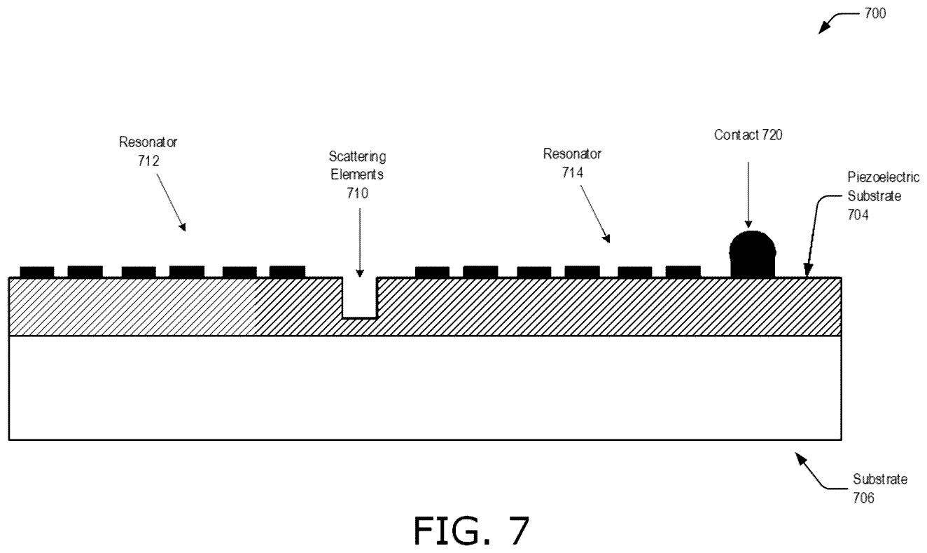

FIG. 7 illustrates aspects of scattering element(s) 710 in accordance with some aspects described herein. As indicated above, the scattering elements can be formed either by addition of material on the piezoelectric substrate, or by forming a void in the device substrate.

The device 700 of FIG. 7 shows a cross section through a scattering element of the scattering elements 710 formed on piezoelectric substrate 704, which is formed on substrate 706. FIG. 7 shows the substrate 706 and piezoelectric substrate 704, but any material stack can be used in different aspects (e.g., as described above with respect to FIG. 3B). Just as described above in FIGS. 5 and 6A-G, multiple scattering elements will be positioned between resonator 712 and resonator 714. Other similar cross sections of the device 700 will not include a void cross section (e.g., in positions between the individual scattering elements) or may include multiple void cross sections (e.g., in implementations similar to the devices 600F, 600G). The device 700 shows a contact 720 which can be used to send or receive electrical signals to a resonator of the device 700. The scattering elements 710 can have dimensions (e.g., depth below the piezoelectric substrate top surface that supports the resonators 712, 714, opening dimensions at the top surface, etc.) of between approximately 0.1 to 10 times the wavelength of the acoustic mode of the resonator 712 or the resonator 714. In some aspects, the depth of the scattering element through the piezoelectric substrate 704 and/or the substrate 706 (e.g., for implementations that include a substrate 706 instead of only the piezoelectric substrate 704) can have a dimension greater than 10 times the resonance wavelength.

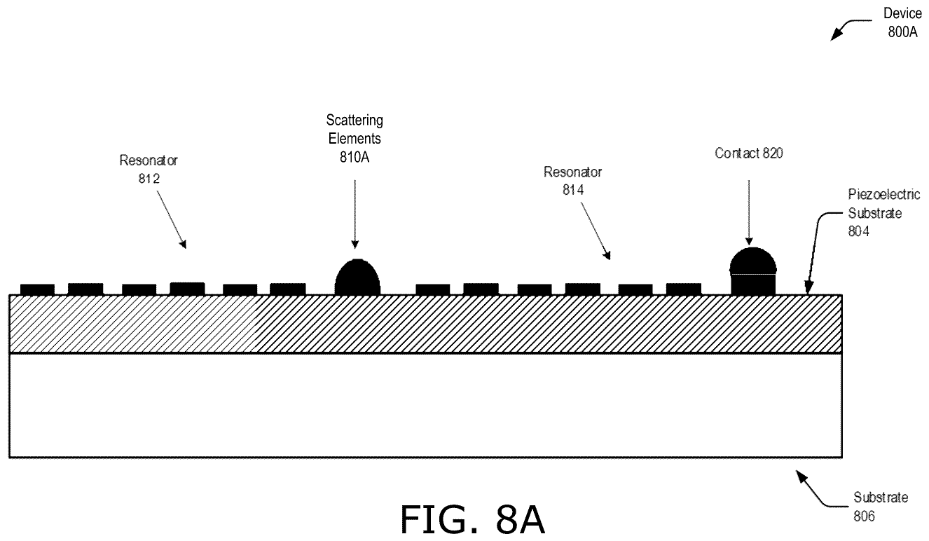

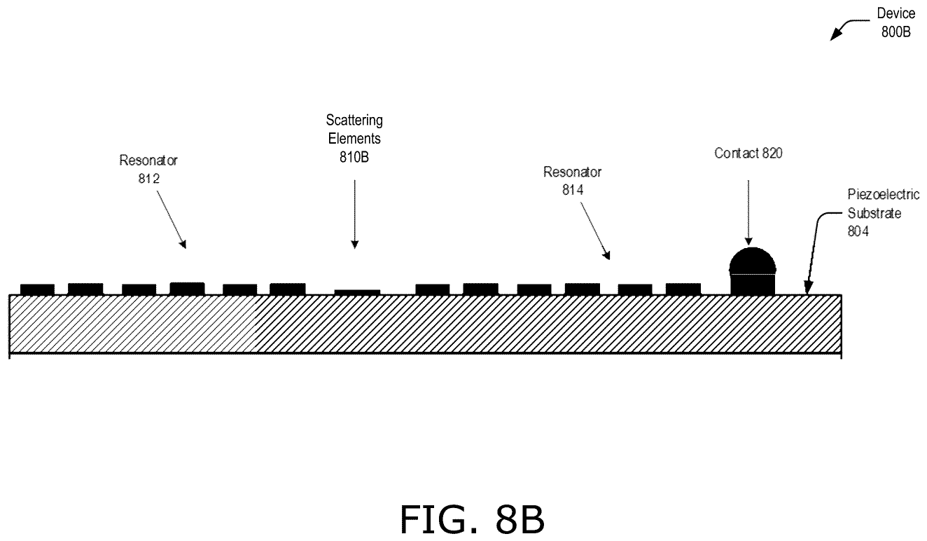

FIG. 8A illustrates a device 800A with scattering element(s) 810 formed using a metal layer. Just as described above, FIG. 8A shows a cross section, with piezoelectric substrate 804 on substrate 806, along with fingers of IDTs of the resonator 812 and the resonator 814 separated by scattering elements 810. A contact 820 is also shown. The cross section of the scattering elements 810A shows a cross section, which can be through a metal layer, a dielectric layer, a semiconducting layer, or any other material that supports scattering of acoustic energy between the resonator 812 and the resonator 814. The Scattering elements 810A of the device 800A can, in some aspects, be formed in a shared process and a shared layer with the contact 820. Such scattering elements 810 will have a metal thickness significantly greater than a thickness of the IDT fingers of the resonator 812. For example, in some aspects, the resonator 812, 814 IDT fingers can have a thickness of approximately 500 nanometers (nm), while the scattering elements 810 can have a thickness of 500 nm, 5000 nm, or more to provide effective scattering and suppression of inter-resonator coupling.

FIG. 8B illustrates a similar device 800B, but with a thinner set of scattering elements 810B having a thinner profile than the scattering elements 810A of FIG. 8A, and without a separate substrate (e.g., the substrate 806) supporting the piezoelectric substrate 804. In some aspects, such scattering elements can have a thickness that is approximately one tenth (e.g. 0.1 times) a thickness of the metal layer of the IDT fingers of the resonators 812, 814. In other aspects, another thickness greater than the thickness of the IDT fingers, or greater than a thickness of 0.1 times a thickness of the IDT fingers is used for the scattering elements 810B. In some aspects, particular dielectric materials can be used, or other such materials can be used, with a thickness of the scattering elements 810B based on characteristics of the material, such that the thickness, along with other geometries of the scattering elements 810B (e.g., length, width, thickness, etc.) are sufficient to disperse acoustic energy between resonators, or between a resonator and a substrate edge, to meet device performance criteria.

Additionally, while aspects described above illustrate acoustic energy dispersion between two resonators, in other aspects, an individual resonator can interfere with itself via acoustic reflections off of a piezoelectric substrate edge, an IC edge, or other such edges of a device. Any aspect above (e.g., FIGS. 7, 8A, 8B) can be implemented with scattering elements between a resonator and a device edge (e.g., piezoelectric layer edge, IC edge, etc.), including void elements such as the scattering elements 710 or the material scattering elements 810A or 810B. In such aspects, the scattering elements can be positioned as shown relative to an edge that would be positioned similarly to the edge of an adjacent resonator (e.g., with an edge at the first IDT of the resonator 714 near the scattering elements 710, etc.)

In accordance with aspects described herein, implementations can include a substrate (e.g., a Si substrate implemented as the substrate 706, the substrate 806, etc.), and a piezoelectric layer (e.g., the piezoelectric substrate 704, the piezoelectric substrate 804, etc.) disposed on the substrate. In other aspects, the piezoelectric layer can be implemented without a separate substrate (e.g., the piezoelectric substrate implemented without an Si substrate 706, etc. as illustrated in FIG. 8B with no Si substrate.) Such a device or apparatus can include a first resonator comprising a first interdigital transducer disposed over a shared surface of the piezoelectric layer and a second resonator comprising a second interdigital transducer disposed over the shared surface of the piezoelectric layer (e.g., the adjacent resonators of any of FIGS. 5, 6A-G, 7, 8 above, etc.). Aspects further include a plurality of scattering elements (e.g., the scattering elements of any of FIGS. 5, 6A-G, 7, 8 above, etc.) positioned between the first resonator and the second resonator. Such scattering elements are configured to disperse acoustic energy from an acoustic mode of the first resonator and to disperse acoustic energy from an acoustic mode of the second resonator. The geometries and placements of the scattering elements are selected to prevent coupling and disperse acoustic energy, and can be selected where a shortest dimension across a scattering element of the plurality of scattering elements is greater than 0.1 times a wavelength of a resonance frequency of the first resonator or a wavelength of a resonance frequency of the second resonator, where a longest dimension across a scattering element of the plurality of scattering elements is less than 10 times a wavelength of a resonance frequency of the first resonator or a wavelength of a resonance frequency of the second resonator, where dimension between adjacent scattering elements of the plurality of scattering elements is greater than 0.1 times a wavelength of a resonance frequency of the first resonator or a wavelength of a resonance frequency of the second resonator, and/or where a longest dimension between adjacent scattering elements of the plurality of scattering elements is less than 10 times a wavelength of a resonance frequency of the first resonator or a wavelength of a resonance frequency of the second resonator.

In accordance with the resonator structures described herein, individual resonators can include a first busbar and a second busbar, an associated first interdigital transducer (IDT) of each resonator comprises a first plurality of IDT electrode fingers comprising first IDT electrode fingers extending from the first busbar toward the second busbar and second IDT electrode fingers extending from the second busbar toward the first busbar in an interdigitated configuration. In conjunction with such resonator structures, the scattering elements between resonators can be aligned along a line perpendicular to the first busbar and the second busbar, such that an extension of a track of the first resonator intersects with the line. For example, if the track 429 of FIG. 4 is extended past where the busbars 402, 404 end, the scattering elements can be placed across this extension of the track to disperse acoustic energy escaping from the end of the track, to prevent interference with an adjacent resonator.

In some aspects, acoustic energy from an acoustic mode can leak from a different alignment other than the track extension described above. For example, in some aspects, positions of resonators or device elements can involve acoustic energy leaking from a resonator anywhere in a vicinity (e.g., close enough to a resonator for acoustic energy to impact a performance of adjacent elements) of the resonator. In various aspects, scattering elements can be positioned in a vicinity of a resonator independent of a resonator orientation to disperse acoustic energy from the resonator.

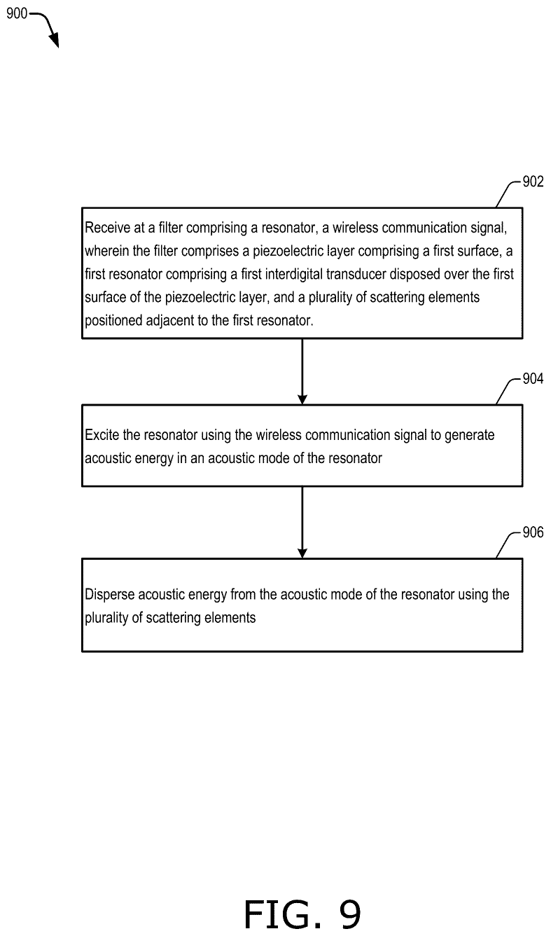

FIG. 9 is a flow diagram illustrating an example method 900 performed by an apparatus comprising at least two electroacoustic resonators separated by a plurality of scattering elements in accordance with aspects described herein. The method 900 is described in the form of a set of blocks that specify operations that can be performed. However, operations are not necessarily limited to the order shown in FIG. 9 or described herein, for the operations may be implemented in alternative orders or in fully or partially overlapping manners. Also, more, fewer, and/or different operations may be implemented to perform the method 900, or an alternative process. In some aspects, the method 900 can be performed by a device comprising circuitry configured for operations of the method 900. In some aspects, control circuitry or one or more processors of the device can be configured to perform the operations. In some aspects, the method 900 can be implemented as instructions in a non-transitory computer readable storage medium that, when executed by one or more processors of the device, cause the device to perform operations of the method 900.

At block 902, the method 900 includes receiving, at a filter comprising a resonator, a wireless communication signal, wherein the filter comprises a piezoelectric layer comprising a first surface, a first resonator comprising a first interdigital transducer disposed over the first surface of the piezoelectric layer, and a plurality of scattering elements positioned adjacent to the first resonator. At block 904, the method 900 includes exciting the resonator using the wireless communication signal to generate acoustic energy in an acoustic mode of the resonator. At block 906, the method 900 includes dispersing acoustic energy from the acoustic mode of the resonator using the plurality of scattering elements.

In some aspects, the method 900 can operate where the piezoelectric layer further comprises an edge, where the plurality of scattering elements are further positioned between the first resonator and the edge, and where the plurality of scattering elements further configured to disperse acoustic energy from an acoustic reflection from the acoustic mode of the first resonator reflected off the edge of the piezoelectric layer.

In some aspects, the method 900 can operate where the piezoelectric layer further comprises a second resonator, with the scattering elements positioned between the first resonator and the second resonator; and where the plurality of scattering elements are configured to disperse acoustic energy from an acoustic mode of the second resonator that is different than an acoustic mode of the first resonator.

In other aspects, the method 900 or other similar methods in accordance with aspects described herein can operate with repeated elements, intervening elements, or using any structure in accordance with any aspect described herein.

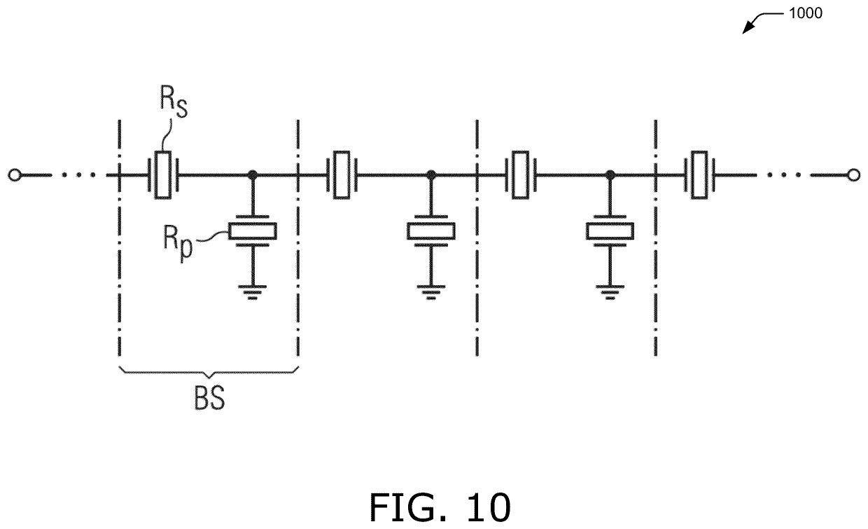

FIG. 10 is a schematic representation of an example filter 1000 that may employ multiple resonators on a shared piezoelectric surface, with scattering elements positioned between at least one pair of resonators. The filter 1000 comprises a ladder-type arrangement of acoustic SAW resonators Rs, Rp (where Rs are series resonators and Rp are parallel resonators).

The ladder-type structure of the filter 1000 comprises a plurality of basic sections. Each basic section comprises at least one series resonator Rs and at least one parallel resonator Rp. The basic sections may be connected together in series in a number of basic sections that is necessary to achieve a desired selectivity. Series resonators Rs that belong to neighbored basic sections may be combined to a common series resonator Rs, and parallel resonators Rp may also be combined if they are directly neighbored and belonging to different basic sections. One basic section provides a basic filter. More basic sections can be added to provide for sufficient selectivity associated with a particular resonator used in the section.

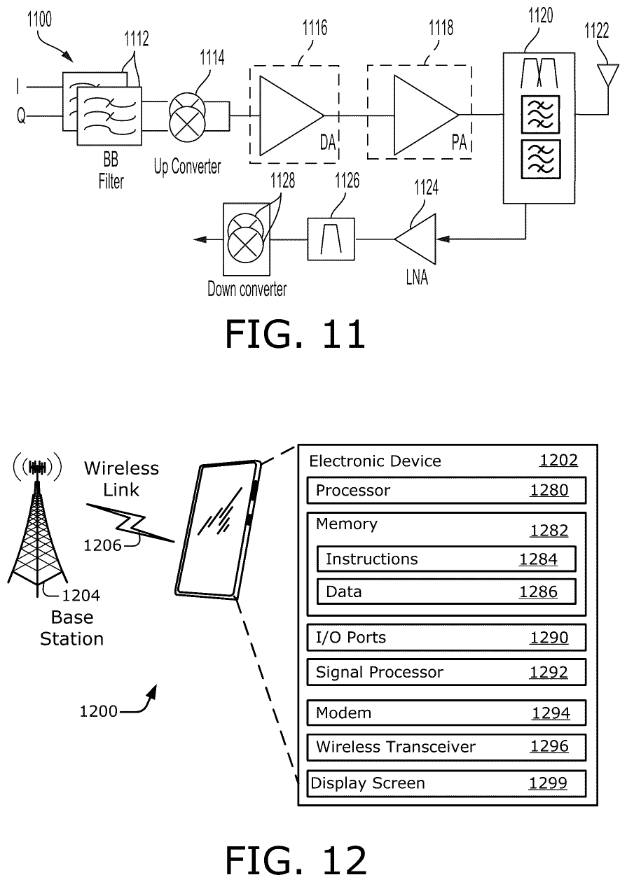

FIG. 11 is a functional block diagram of at least a portion of an example of a simplified wireless transceiver circuit 1100 in which resonators on a shared piezoelectric surface with scattering elements may be employed. The transceiver circuit 1100 is configured to receive signals/information for transmission (shown as I and Q values) which is provided to one or more base band filters 1112. The filtered output is provided to one or more mixers 1114. The output from the one or more mixers 1114 is provided to a driver amplifier 1116 whose output is provided to a power amplifier 1118 to produce an amplified signal for transmission. The amplified signal is output to the antenna 1122 through one or more filters 1120 (e.g., duplexers if used as a frequency division duplex transceiver or other filters). The one or more filters 1120 may include the disclosed DMS resonator. The antenna 1122 may be used for both wirelessly transmitting and receiving data. The transceiver circuit 1100 includes a receive path through the one or more filters 1120 to be provided to a low noise amplifier (LNA) 1124 and a further filter 1126 and then down-converted from the receive frequency to a baseband frequency through one or more mixer circuits 1128 before the signal is further processed (e.g., provided to an analog digital converter and then demodulated or otherwise processed in the digital domain). There may be separate filters for the receive circuit (e.g., may have a separate antenna or have separate receive filters) that may be implemented using the disclosed resonators on a shared piezoelectric surface with scattering elements.

FIG. 12 is a diagram of an environment 1200 that includes an electronic device 1202 that includes a wireless transceiver 1296, such as the transceiver circuit 1100 of FIG. 11. In some aspects, the electronic device 1202 includes a display screen 1299 that can be used to display information associated with data transmitted via wireless link 1206 and processed using components of electronic device 1202 described below. Other aspects of an electronic device in accordance with aspects described herein using a low phase delay filter for multi-band communication can be configured without a display screen. In the environment 1200, the electronic device 1202 communicates with a base station 1204 through a wireless link 1206. As shown, the electronic device 1202 is depicted as a smart phone. However, the electronic device 1202 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, an automobile including a vehicle-based communication system, Internet of Things (IoT) device, sensor or security device, asset tracker, and so forth.

The base station 1204 communicates with the electronic device 1202 via the wireless link 1206, which may be implemented as any suitable type of wireless link. Although depicted as a base station tower of a cellular radio network, the base station 1204 may represent or be implemented as another device, such as a satellite, terrestrial broadcast tower, access point, peer to peer device, mesh network node, fiber optic line, another electronic device generally as described above, and so forth. Hence, the electronic device 1202 may communicate with the base station 1204 or another device via a wired connection, a wireless connection, or a combination thereof. The wireless link 1206 can include a downlink of data or control information communicated from the base station 1204 to the electronic device 1202 and an uplink of other data or control information communicated from the electronic device 1202 to the base station 1204. The wireless link 1206 may be implemented using any suitable communication protocol or standard, such as 3rd Generation Partnership Project Long-Term Evolution (3GPP LTE, 3GPP NR 5G), IEEE 802.11, IEEE 802.16, Bluetooth™, and so forth.

The electronic device 1202 includes a processor 1280 and a memory 1282. The memory 1282 may be or form a portion of a computer readable storage medium. The processor 1280 may include any type of processor, such as an application processor or a multi-core processor, that is configured to execute processor-executable instructions (e.g., code) stored by the memory 1282. The memory 1282 may include any suitable type of data storage media, such as volatile memory (e.g., random access memory (RAM)), non-volatile memory (e.g., Flash memory), optical media, magnetic media (e.g., disk or tape), and so forth. In the context of the disclosure, the memory 1282 is implemented to store instructions 1284, data 1286, and other information of the electronic device 1202, and thus when configured as or part of a computer readable storage medium, the memory 1282 does not include transitory propagating signals or carrier waves.

The electronic device 1202 may also include input/output ports 1290. The I/O ports 1290 enable data exchanges or interaction with other devices, networks, or users or between components of the device.

The electronic device 1202 may further include a signal processor (SP) 1292 (e.g., such as a digital signal processor (DSP)). The signal processor 1292 may function similar to the processor and may be of capable executing instructions and/or processing information in conjunction with the memory 1282.

For communication purposes, the electronic device 1202 also includes a modem 1294, a wireless transceiver 1296, and an antenna (not shown). The wireless transceiver 1296 provides connectivity to respective networks and other electronic devices connected therewith using radio-frequency (RF) wireless signals and may include the transceiver circuit 1100 of FIG. 11. The wireless transceiver 1296 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

The various operations of methods described above may be performed by any suitable means capable of performing the corresponding functions. The means may include various hardware and/or software component(s) and/or module(s), including, but not limited to a circuit, an application-specific integrated circuit (ASIC), or processor.

By way of aspect, an element, or any portion of an element, or any combination of elements described herein may be implemented as a “processing system” that includes one or more processors. Aspects of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout the disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more aspect embodiments, the functions or circuitry blocks described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of aspect, and not limitation, such computer-readable media can include a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer. In some aspects, components described with circuitry may be implemented by hardware, software, or any combination thereof.

The phrase “coupled to” and the term “coupled” refers to any component that is physically connected to another component either directly or indirectly, and/or any component that is in communication with another component (e.g., connected to the other component over a wired or wireless connection, and/or other suitable communication interface) either directly or indirectly.

Generally, where there are operations illustrated in figures, those operations may have corresponding counterpart means-plus-function components with similar numbering.

As used herein, the term “determining” encompasses a wide variety of actions. For some aspects, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

The following is a set of non-limiting aspects in accordance with the details provided herein:

Aspect 1. An apparatus comprising: a piezoelectric layer comprising a shared surface; a first resonator comprising a first interdigital transducer disposed over the shared surface of the piezoelectric layer; a second resonator comprising a second interdigital transducer disposed over the shared surface of the piezoelectric layer; and a plurality of scattering elements positioned between the first resonator and the second resonator.

Aspect 2. The apparatus of Aspect 1, wherein the plurality of scattering elements are configured to disperse acoustic energy from an acoustic mode of the first resonator and to disperse acoustic energy from an acoustic mode of the second resonator.

Aspect 3. The apparatus of any of Aspects 1 to 2, wherein a shortest dimension across a scattering element of the plurality of scattering elements is greater than 0.1 times a wavelength of a resonance frequency of the first resonator or a wavelength of a resonance frequency of the second resonator.

Aspect 4. The apparatus of any of Aspects 1 to 3, wherein a longest dimension across a scattering element of the plurality of scattering elements is less than 10 times a wavelength of a resonance frequency of the first resonator or a wavelength of a resonance frequency of the second resonator.

Aspect 5. The apparatus of any of Aspects 1 to 4, wherein a shortest dimension between adjacent scattering elements of the plurality of scattering elements is greater than 0.1 times a wavelength of a resonance frequency of the first resonator or a wavelength of a resonance frequency of the second resonator.

Aspect 6. The apparatus of any of Aspects 1 to 5, wherein a longest dimension between adjacent scattering elements of the plurality of scattering elements is less than 10 times a wavelength of a resonance frequency of the first resonator or a wavelength of a resonance frequency of the second resonator.

Aspect 7. The apparatus of any of Aspects 1 to 6, wherein the first resonator further comprises: a first busbar; and a second busbar; wherein the first interdigital transducer (IDT) comprises a first plurality of IDT electrode fingers comprising first IDT electrode fingers extending from the first busbar toward the second busbar and second IDT electrode fingers extending from the second busbar toward the first busbar in an interdigitated configuration.

Aspect 8. The apparatus of Aspect 7, wherein the plurality of scattering elements are aligned along a line perpendicular to the first busbar and the second busbar, such that an extension of a track of the first resonator intersects with the line.

Aspect 9. The apparatus of Aspect 7, wherein the plurality of scattering elements are positioned in a path extending from a track of the first resonator.

Aspect 10. The apparatus of Aspect 7, wherein the plurality of scattering elements are positioned in a vicinity of a resonator independent of a resonator orientation.

Aspect 11. The apparatus of Aspect 7, further comprising a metal contact coupled to the first busbar, wherein the plurality of scattering elements are formed in a shared layer with the metal contact.

Aspect 12. The apparatus of any of Aspects 1 to 11, wherein the plurality of scattering elements comprise voids within the piezoelectric layer.

Aspect 13. The apparatus of Aspect 12, wherein the plurality of scattering elements have a thickness that is at least 0.1 times a thickness of a metal layer of the first interdigital transducer.

Aspect 14. The apparatus of any of Aspects 1 to 13, wherein the plurality of scattering elements comprise metal, dielectric, or semiconducting material disposed on the piezoelectric layer.

Aspect 15. The apparatus of any of Aspects 1 to 14, wherein the plurality of scattering elements comprise circular geometries.

Aspect 16. The apparatus of any of Aspects 1 to 15, wherein the plurality of scattering elements comprise elements with two or more distinct geometries.

Aspect 17. The apparatus of any of Aspects 1 to 16, further comprising a second plurality of scattering elements positioned between the first resonator and an edge of the piezoelectric layer

Aspect 18. An apparatus comprising: a piezoelectric layer comprising a first surface and a first edge; a first resonator comprising a first interdigital transducer disposed over the first surface of the piezoelectric layer; and a plurality of scattering elements positioned between the first resonator and the first edge of the piezoelectric layer.

Aspect 19. The apparatus of Aspect 18, wherein the plurality of scattering elements are configured to disperse acoustic energy from an acoustic mode of the first resonator, and to disperse acoustic energy from an acoustic reflection from the acoustic mode of the first resonator reflected off the first edge of the piezoelectric layer.

Aspect 20. The apparatus of any of Aspects 18 to 19, wherein the first resonator further comprises: a first busbar; and a second busbar; wherein the first interdigital transducer (IDT) comprises a first plurality of IDT electrode fingers comprising first IDT electrode fingers extending from the first busbar toward the second busbar and second IDT electrode fingers extending from the second busbar toward the first busbar in an interdigitated configuration.

Aspect 21. The apparatus of Aspect 20, wherein the plurality of scattering elements are aligned along a line perpendicular to the first busbar and the second busbar, such that an extension of a track of the first resonator intersects with the line.

Aspect 22. The apparatus of Aspect 20, wherein the plurality of scattering elements are positioned in a vicinity of a resonator independent of a resonator orientation.

Aspect 23. The apparatus of any of Aspects 18 to 22, wherein the plurality of scattering elements comprise voids within the piezoelectric layer.

Aspect 24. The apparatus of any of Aspects 18 to 23, wherein the plurality of scattering elements comprise material disposed on the piezoelectric layer.

Aspect 25. The apparatus of Aspect 24, wherein the plurality of scattering elements have a thickness that is at least one tenth a thickness of a metal layer of the first interdigital transducer.

Aspect 26. The apparatus of any of Aspects 18 to 25, wherein the plurality of scattering elements comprise elements with two or more distinct geometries.

Aspect 27. A method comprising: receiving, at a filter comprising a resonator, a wireless communication signal, wherein the filter comprises a piezoelectric layer comprising a first surface, a first resonator comprising a first interdigital transducer disposed over the first surface of the piezoelectric layer, and a plurality of scattering elements positioned adjacent to the first resonator; exciting the resonator using the wireless communication signal to generate acoustic energy in an acoustic mode of the resonator; and dispersing acoustic energy from the acoustic mode of the resonator using the plurality of scattering elements.

Aspect 28. The method of Aspect 27, wherein the piezoelectric layer further comprises an edge; wherein the plurality of scattering elements are further positioned between the first resonator and the edge; and wherein the plurality of scattering elements further configured to disperse acoustic energy from an acoustic reflection from the acoustic mode of the first resonator reflected off the edge of the piezoelectric layer.

Aspect 29. The method of Aspect 27, wherein the piezoelectric layer further comprises a second resonator, with the scattering elements positioned between the first resonator and the second resonator; and wherein the plurality of scattering elements are configured to disperse acoustic energy from an acoustic mode of the second resonator that is different than an acoustic mode of the first resonator.

Aspect 30. The method of Aspect 29, wherein a shortest dimension across a scattering element of the plurality of scattering elements is greater than 0.1 times a wavelength of a resonance frequency of the first resonator or a wavelength of a resonance frequency of the second resonator; wherein a longest dimension across a scattering element of the plurality of scattering elements is less than 10 times a wavelength of a resonance frequency of the first resonator or a wavelength of a resonance frequency of the second resonator; wherein a shortest dimension between adjacent scattering elements of the plurality of scattering elements is greater than 0.1 times a wavelength of a resonance frequency of the first resonator or a wavelength of a resonance frequency of the second resonator; and wherein a longest dimension between adjacent scattering elements of the plurality of scattering elements is less than 10 times a wavelength of a resonance frequency of the first resonator or a wavelength of a resonance frequency of the second resonator.

Aspect 31. The method of any of Aspects 27 to 29 performed using any apparatus of Aspects 1-26 above.

What is claimed is:

1. An apparatus comprising:
a piezoelectric layer comprising a shared surface;
a first resonator comprising a first interdigital transducer disposed over the shared surface of the piezoelectric layer;
a second resonator comprising a second interdigital transducer disposed over the shared surface of the piezoelectric layer; and
a plurality of scattering elements positioned between the first resonator and the second resonator.

2. The apparatus of claim 1, wherein the plurality of scattering elements are configured to disperse acoustic energy from an acoustic mode of the first resonator and to disperse acoustic energy from an acoustic mode of the second resonator.

3. The apparatus of claim 1, wherein a shortest dimension across a scattering element of the plurality of scattering elements is greater than 0.1 times a wavelength of a resonance frequency of the first resonator or a wavelength of a resonance frequency of the second resonator.

4. The apparatus of claim 1, wherein a longest dimension across a scattering element of the plurality of scattering elements is less than 10 times a wavelength of a resonance frequency of the first resonator or a wavelength of a resonance frequency of the second resonator.

5. The apparatus of claim 1, wherein a shortest dimension between adjacent scattering elements of the plurality of scattering elements is greater than 0.1 times a wavelength of a resonance frequency of the first resonator or a wavelength of a resonance frequency of the second resonator.

6. The apparatus of claim 1, wherein a longest dimension between adjacent scattering elements of the plurality of scattering elements is less than 10 times a wavelength of a resonance frequency of the first resonator or a wavelength of a resonance frequency of the second resonator.

7. The apparatus of claim 1, wherein the first resonator further comprises:
a first busbar; and
a second busbar;
wherein the first interdigital transducer (IDT) comprises a first plurality of IDT electrode fingers comprising first IDT electrode fingers extending from the first busbar toward the second busbar and second IDT electrode fingers extending from the second busbar toward the first busbar in an interdigitated configuration.

8. The apparatus of claim 7, wherein the plurality of scattering elements are aligned along a line perpendicular to the first busbar and the second busbar, such that an extension of a track of the first resonator intersects with the line.

9. The apparatus of claim 7, wherein the plurality of scattering elements are positioned in a path extending from a track of the first resonator.

10. The apparatus of claim 7, wherein the plurality of scattering elements are positioned in a vicinity of a resonator independent of a resonator orientation.

11. The apparatus of claim 1, wherein the plurality of scattering elements comprise voids within the piezoelectric layer.

12. The apparatus of claim 1, wherein the plurality of scattering elements comprise metal, dielectric, or semiconducting material disposed on the piezoelectric layer.

13. The apparatus of claim 11, wherein the plurality of scattering elements have a thickness that is at least 0.1 times a thickness of a metal layer of the first interdigital transducer.

14. The apparatus of claim 7, further comprising a metal contact coupled to the first busbar, wherein the plurality of scattering elements are formed in a shared layer with the metal contact.

15. The apparatus of claim 1, wherein the plurality of scattering elements comprise circular geometries.

16. The apparatus of claim 1, wherein the plurality of scattering elements comprise elements with two or more distinct geometries.

17. The apparatus of claim 1, further comprising a second plurality of scattering elements positioned between the first resonator and an edge of the piezoelectric layer.

18. An apparatus comprising:
a piezoelectric layer comprising a first surface and a first edge;
a first resonator comprising a first interdigital transducer disposed over the first surface of the piezoelectric layer; and
a plurality of scattering elements positioned between the first resonator and the first edge of the piezoelectric layer.

19. The apparatus of claim 18, wherein the plurality of scattering elements are configured to disperse acoustic energy from an acoustic mode of the first resonator, and to disperse acoustic energy from an acoustic reflection from the acoustic mode of the first resonator reflected off the first edge of the piezoelectric layer.

20. The apparatus of claim 18, wherein the first resonator further comprises:
a first busbar; and
a second busbar;
wherein the first interdigital transducer (IDT) comprises a first plurality of IDT electrode fingers comprising first IDT electrode fingers extending from the first busbar toward the second busbar and second IDT electrode fingers extending from the second busbar toward the first busbar in an interdigitated configuration.

21. The apparatus of claim 20, wherein the plurality of scattering elements are aligned along a line perpendicular to the first busbar and the second busbar, such that an extension of a track of the first resonator intersects with the line.

22. The apparatus of claim 20, wherein the plurality of scattering elements are positioned in a vicinity of a resonator independent of a resonator orientation.

23. The apparatus of claim 18, wherein the plurality of scattering elements comprise voids within the piezoelectric layer.

24. The apparatus of claim 18, wherein the plurality of scattering elements comprise material disposed on the piezoelectric layer.

25. The apparatus of claim 24, wherein the plurality of scattering elements have a thickness that is at least one tenth a thickness of a metal layer of the first interdigital transducer.

26. The apparatus of claim 18, wherein the plurality of scattering elements comprise elements with two or more distinct geometries.

27. A method comprising:
receiving, at a filter comprising a resonator, a wireless communication signal, wherein the filter comprises a piezoelectric layer comprising a first surface, a first resonator comprising a first interdigital transducer disposed over the first surface of the piezoelectric layer, and a plurality of scattering elements positioned adjacent to the first resonator;
exciting the resonator using the wireless communication signal to generate acoustic energy in an acoustic mode of the resonator; and
dispersing acoustic energy from the acoustic mode of the resonator using the plurality of scattering elements.

28. The method of claim 27, wherein:
the piezoelectric layer further comprises an edge; and
the plurality of scattering elements are further positioned between the first resonator and the edge; and
wherein the plurality of scattering elements further configured to disperse acoustic energy from an acoustic reflection from the acoustic mode of the first resonator reflected off the edge of the piezoelectric layer.

29. The method of claim 27, wherein:
the piezoelectric layer further comprises a second resonator, with the plurality of scattering elements positioned between the first resonator and the second resonator; and
the plurality of scattering elements are configured to disperse acoustic energy from an acoustic mode of the second resonator that is different than an acoustic mode of the first resonator.

30. The method of claim 29, wherein:
a shortest dimension across a scattering element of the plurality of scattering elements is greater than 0.1 times a wavelength of a resonance frequency of the first resonator or a wavelength of a resonance frequency of the second resonator;
a longest dimension across a scattering element of the plurality of scattering elements is less than 10 times a wavelength of a resonance frequency of the first resonator or a wavelength of a resonance frequency of the second resonator;
a shortest dimension between adjacent scattering elements of the plurality of scattering elements is greater than 0.1 times a wavelength of a resonance frequency of the first resonator or a wavelength of a resonance frequency of the second resonator; and
a longest dimension between adjacent scattering elements of the plurality of scattering elements is less than 10 times a wavelength of a resonance frequency of the first resonator or a wavelength of a resonance frequency of the second resonator.
